(19) United States
(12) Patent Application Publication
(10) Pub. No.: US 2015/0340656 A1
(43) Pub. Date: Nov. 26, 2015

(54) BUCKLED ORGANIC LIGHT EMITTING DIODE FOR LIGHT EXTRACTION

(71) Applicant: University of Florida Research Foundation, Inc., Gainesville, FL (US)

(72) Inventors: Franky So, Gainesville, FL (US); Wonhoe Koo, Gainesville, FL (US)

(73) Assignee: University of Florida Research Foundation, Inc., Gainesville, FL (US)

(21) Appl. No.: 14/410,966

(22) PCT Filed: Jun. 25, 2013
(86) PCT No.: PCT/US2013/047562

§ 371 Date: Dec. 23, 2014

Related U.S. Application Data
(60) Provisional application No. 61/663,860, filed on Jun. 25, 2012.

(51) Int. Cl. H01L 51/52; H01L 51/56; H01L 51/50; H01L 51/00

(52) U.S. Cl. CPC H01L 51/5262; H01L 51/0096; H01L 51/56; H01L 51/5209; H01L 51/5056; H01L 51/5225; H01L 51/0094; H01L 2251/301; H01L 2251/303; H01L 2251/558

(57) ABSTRACT

Embodiments of the invention are directed to a layered organic light emitting diode (OLED) device comprising a buckled structure that provides an improved light output relative to flat OLED devices. The buckled structure has a fine buckling with a quasi-periodicity of 100 to 700 nm and a gross buckling of 10 to 20 μm. Embodiments of the invention are directed to a method of producing the OLED device comprising a buckled structure, where a transparent substrate is coated with a transparent elastomeric layer, upon which a thin metal layer of 20 to 100 nm is deposited at an elevated temperature. Upon cooling to ambient temperature, the metal layer buckles with the formation of a fine buckling with a quasi-periodicity of 100 to 700 nm and a gross buckling of 10 to 20 μm. The metal layer is oxidized to a transparent metal oxide layer with the retention of the buckling. Subsequent steps comprising deposition of at least an anode layer, an electroluminescence layer, and a cathode layer forms an OLED that has a buckling structure resulting from the buckled metal structure formed upon cooling.

### CROSS-REFERENCE TO RELATED APPLICATION

The present application claims the benefit of U.S. Provisional Application Ser. No. 61/663,860, filed Jun. 25, 2012, which is hereby incorporated by reference herein in its entirety, including any figures, tables, or drawings.

BACKGROUND OF INVENTION

Organic light emitting diodes (OLEDs) suffer from a relatively low efficiency of emitted light relative to that generated because of light trapping because of the refractive index mismatches between the air (n=1), glass substrate (n=1.52), and an electrode/active layer, for example an ITO/organic layer (˜1.7 to ˜2.0) in waveguide modes. To recover a portion of the lost light, the imposition of a periodic microstructure into the OLED has been studied. Unfortunately, although improvement of the light output has occurred, the cost to achieve the periodic microstructure is that of complicating the process with lithographic and imprinting steps to prepare and transfer the microstructure to the OLED.

Bowden et al., Nature 1998, 393, 146-9 demonstrated the preparation of buckled structure by the deposition of metal films on a thermally expanded 1 cm thick polydimethylsiloxane (PDMS) rubber film upon subsequent cooling of the films where buckling of the metal film results from the compressive stress imposed by the cooling rubber where the buckles display a uniform wavelength of 20-50 micrometers. The buckles had periodicities between 20 and 50 μm; with a depth from the crest to the trough of 1.5 μm for metal deposition performed without external heating, where the temperature imposed by the hot evaporating metal appeared to result in a surface temperature of about 110° C., to 3.9 μm for deposition conducted at 300° C. Regularly buckled semiconductor ribbons were disclosed by Khang et al., Science 2006, 311, 208-12 and Jiang et al., Applied Physics Letters 2007, 90, 133119, where a PDMS rubber is deformed along a single axis to result in a periodically buckled semiconductor ribbon with periodicities with lengths in excess of a micron. Yu et al. Applied Physics Letters 2010, 96, 041111 demonstrated regular buckled patterns with submicron periodicity by controlling the thickness of the metal film to thicknesses on the order of 10 nm on 1 mm thick PDMS rubber strips that were pre-stretched along one axis at a desired pre-strain.

Koo et al., Nature Photonics 2010, 4, 222-6 extended the use of buckled metal surfaces to the preparation of OLEDs. PDMS was cured at 100° C. and an aluminum layer was deposited on the rubber at a thickness of about 10 nm. Upon cooling a quasi-periodic buckled surface formed and was used to form a PDMS replica of the buckled surface which is subsequently metallated with Al, used to form a UV cured resin replica of the PDMS replica for use as a master template. The metal template was subsequently used to form a second PDMS replica after Al deposition, followed by forming a second resin replica, which upon removal of the PDMS replica is UV-ozone treated and sputtered with an ITO glass to form an anode and subsequently an OLED after deposition of a hole transport layer, a light emission-electron transport layer, an electron injection layer, and an Al cathode layer. This OLED had an enhancement of the emitted intensity of about 2.2 fold at 525 nm and about fourfold at 655 nm.

There remains a need to achieve a periodic or a quasi-periodic microstructure that does not require a significant departure from existing fabrication techniques of an OLED. Particularly desirable is a quasi-periodic structure where the observed efficiency of the light output is improved by the relationship of the emission wavelength to the polar angles and azimuthal angles of the quasi-periodic structure.

### BRIEF SUMMARY

Embodiments of the invention are directed to organic light emitting diode (OLED) devices, designed to emit light through a transparent substrate that is bound to a transparent elastomeric layer that is covered with a transparent metal oxide layer upon which is stacked a transparent anode layer, an electroluminescent layer, and a cathode layer, where the OLED device has a quasi-periodic buckling that displays a fine buckling superimposed on a gross buckling that increases the light extracted from the OLED relative to one absent the buckling structure. The fine buckling has a quasi-periodicity of 100 to 700 nm and the gross buckling has a quasi-periodicity of 10 to 20 μm. The transparent substrate can be glass or other rigid structure and the elastomer can be polydimethylsiloxane (PDMS) or other transparent elastomer.

Other embodiments of the invention are directed to methods of preparing an OLED device that comprise steps to deposit a transparent elastomeric layer on a transparent substrate; depositing a metal layer of 5 to 100 nm on the transparent elastomeric layer, where a portion of the metal layer can be oxidized upon contact with the elastomer; allowing the deposited metal layer to cool to ambient temperature, which generates the buckling;

optionally further oxidizing the metal to achieve a metal oxide layer on the elastomer; depositing a transparent anode layer; an electroluminescent layer; and a cathode layer.

### BRIEF DESCRIPTION OF DRAWINGS

FIG. 1 shows a cross-section of a portion of a fine buckling structure of an organic light emitting diode (OLED) device that has a quasi-periodic grating over the entire surface that comprises a fine buckling, according to an embodiment of the invention, wherein the relative thickness of the elastomer 2 and the OLED layers 3-7 are not necessarily to scale.

FIG. 2 shows a representation of an OLED cross-section where the fine structure by buckling is positioned over a gross buckling of the device, where the fine buckling of FIG. 1 is within the boxed portion of the top structure; however, an OLED according to an embodiment of the invention does not necessarily have the continuous periodicity of the fine structure over a single period of the gross structure, but will generally have a fine periodicity that extends in a single direction for only a few periods of the fine buckling over the period of a gross buckling.

FIG. 3 shows atomic force microscopy (AMF) images of an exemplary OLED with a Quasi periodic grating where (a) the fine buckling is shown in a 5 μm×5 μm image after the deposition of a 15 nm thick Al on PDMS, (b) a gross buckling image in a 96.4 μm×96.4 μm image after deposition of a 70 nm thick ITO layer on the Al layer, and (c) a gross buckling image in a 97.3 μm×97.3 μm image after subsequent depositions of a 50 nm thick NPB layer, a 60 nm thick Algₐ layer, and a 90 nm thick Al layer on the ITO layer of (b), according to an embodiment of the invention.

FIG. 4 shows plots of the current efficiency (cd/A) as a function of luminance for OLEDs formed without buckles, with current efficiencies of about 1.7 cd/A (black) and for OLEDs formed with buckles, according to an embodiment of the invention, which display current efficiencies of more than 3 cd/A (gray).

DETAILED DISCLOSURE

Embodiments of the invention are directed to an organic light emitting diode (OLED) comprising a quasi-periodic grating that is a buckling structure. In an embodiment of the invention, the buckling comprises a fine buckling upon a gross buckling. The buckling is distal to the light exiting face and is situated on a transparent elastomer comprising layer adjacent to a transparent substrate at the light exiting face of the OLED. In an exemplary embodiment of the invention, the elastomer comprises silicone. The fine buckling structure is of dimensions that extract the waveguide modes of the OLED and have periodicities or quasi-periodicities of about 100 to about 700 μm. The gross buckling has a periodicity or quasi-periodicities on the order of about 10 to 20 μm. Quasi-periodic buckling is one where approximately the same periodicity extends for a finite distance along any line parallel to the substrate for a few periods, for example, one to six periods, before a change of orientation of the bucking occurs and the line may be traversing along a maximum or minimum feature of the buckling or any other cross-section of the fine buckling.

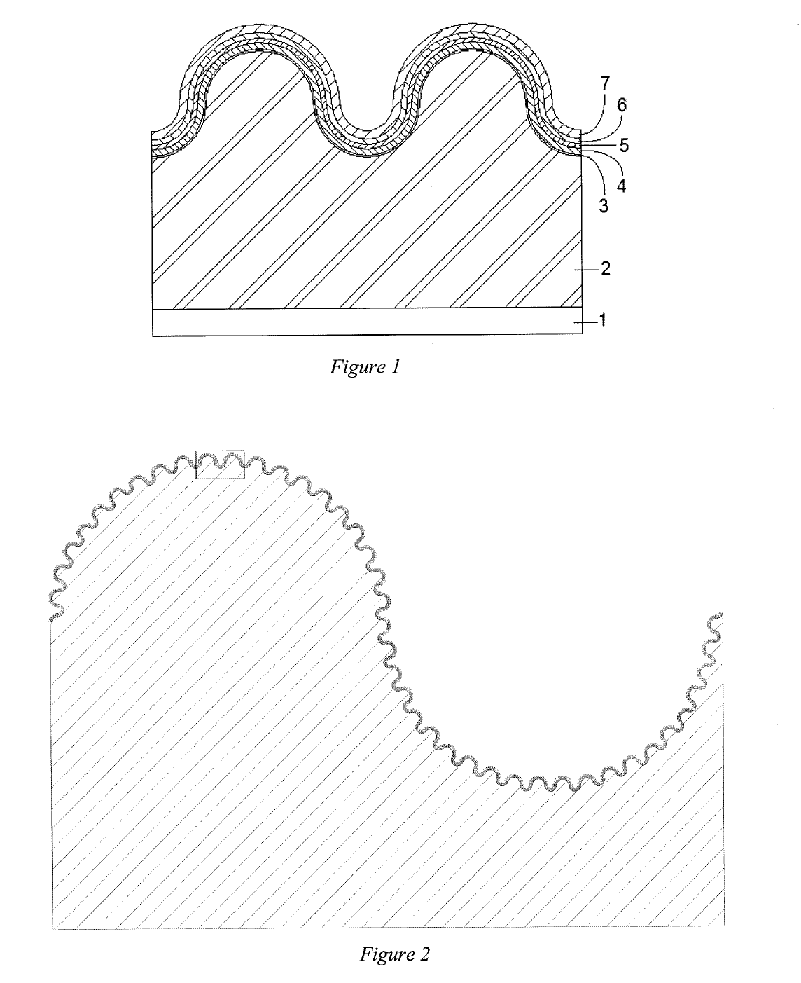

According to an embodiment of the invention, the OLED, as illustrated for the fine buckling in FIG. 1, is a “bottom emission” device that includes a transparent (bottom) substrate 1 supporting a transparent elastomer layer 2, a transparent metal oxide layer 3, a transparent anode layer 4, a hole transporting layer 5, an electroluminescent layer 6, and a cathode layer 7. In an exemplary embodiment of the invention, the substrate 1 can be glass, the elastomer layer 2 can comprise silicone, the metal oxide layer 3 can comprise aluminum oxide, the anode 4 can comprise indium tin oxide (ITO), the hole transporting layer 5 can comprise N,N′-diphenyl-N,N′-bis(1-naphthyl)-(1,1′-biphenyl)-4,4′-diamine (NPB), the electroluminescent layer 6 can comprise tris-(8-hydroxyquinoline)aluminium (Alq₃), and the cathode layer 7 can comprise aluminum metal.

Another embodiment of the invention is directed to producing an OLED device with improved light output. The method involves the formation of a transparent elastomer as a film on a transparent substrate. The transparent substrate can be a glass, or it can be a polymeric structure, such as a thermoplastic or a thermoset. The transparent substrate is capable of being warmed to at least 100° C. without distortion. The elastomer can be formed by cast as an elastomer precursor on the substrate followed by curing the precursor to the elastomer. The elastomer precursor can be spin coated, dip coated, doctor bladed, rolled, or deposited in any manner from a precursor in a liquid state, either as a neat precursor or a precursor in solution, optionally with a cross-linking agent and/or catalyst. The elastomer can be an organic elastomer, for example, polybutadiene, polyisoprene, polychloroprene, poly(styrene-block-butadiene), poly(butadiene-co-acrylonitrile), poly(ethylene-co-propylene), poly(ethylene-co-propylene-co-butadiene, a polyacrylate or a fluoroelastomer. The elastomer can be an inorganic rubber, for example, silicone, fluorosilicone, or a polyphosphazine. The precursor to the elastomer can be monomeric, oligomeric, or polymeric and can be formed upon polymerization and/or crosslinking, which can be performed with the inclusion of a catalyst, initiator, or crosslinking agent, and can be gelled by heat or radiation. The deposited elastomer can be surface treated if desired; for example, the surface can be oxidized or treated with a functional agent to modify the surface in a manner that promotes adhesion to a metal coating. The elastomer can be deposited with a thickness of about 20 to about 1,000 μm or more in thickness.

After deposition of the elastomer, a thin metal film can be deposited on the elastomeric film. The deposition can be carried out on the elastomer over a large range of temperatures above ambient temperature but below the decomposition temperature of the elastomer. The metal can be deposited as a film of about 5 nm to about 100 nm in thickness. After deposition of the metal film, the temperature is permitted to cool to ambient temperature upon which the adhered metal film is obliged to buckle due to the compressive stress imposed due to the large difference in the thermal expansion coefficients of the elastomer and the metal. The metal can be any metal that does not form a highly colored oxide. The metal can be, but is not restricted to, aluminum, magnesium, calcium, zinc, tin or cadmium. The metal can be an alloy, for example, zinc and aluminum, zinc or gallium, or tin and indium. The metal or metal alloy can be oxidized using an oxidizer, for example, ozone with ultraviolet radiation, and can be an oxidizing surface of a silicone rubber that has been treated with ozone and ultraviolet radiation. The metal oxide can be insulating, semiconducting or conducting. For example, the metal can be indium doped tin that forms an Indium tin oxide glass directly from the buckled metal. The quasi-periodicity of the buckling can be controlled by the thickness of the deposited metal layer. As the metal is deposited at an elevated temperature, for example, 80 to 200° C., the buckling occurs during the cooling of the elastomer.

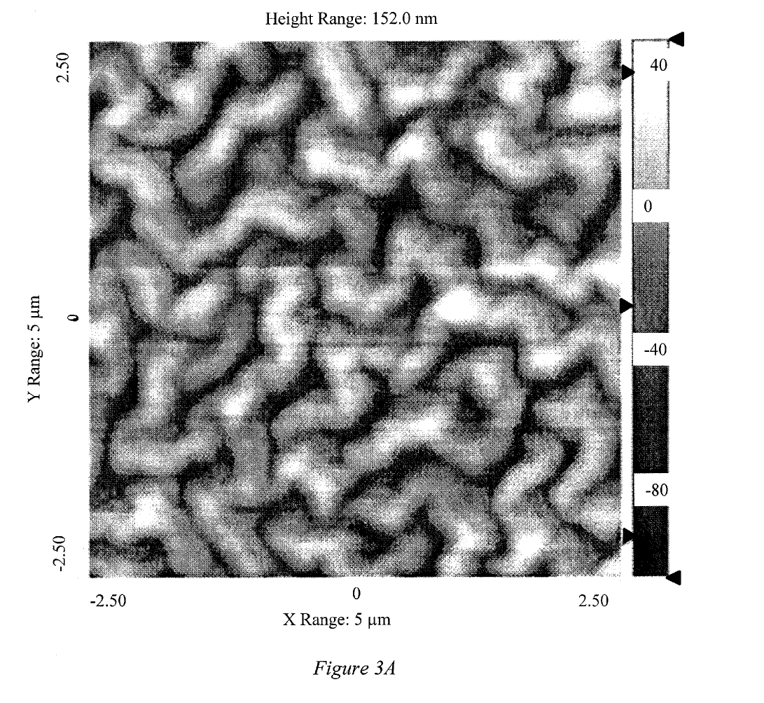

Subsequent to the deposition of the metal and its conversion to the metal oxide, a transparent conductor can be deposited on the metal oxide. For example, a conductive metal oxide, such as but not restricted to, indium tin oxide, aluminum zinc oxide, gallium zinc oxide, or indium zinc oxide, can be deposited on the buckled metal oxide surface. In another embodiment of the invention, an ultrathin highly transmissive metal layer, for example a 5 to 15 nm aluminum layer, can be deposited on the metal oxide. In another embodiment of the invention, an ultrathin metal layer, for example, a 2 to 5 nm layer, can be connected by a metal grid of thicker metal lines, for example 100 to 1,000 nm lines spaced apart by 1 to 15 μm to form an electrode. The deposition can be conformal or non-conformal with the buckled metal oxide, although some degree of periodicity or quasi-periodicity is retained. An imaged periodicity can be that of the gross periodicity and not the fine periodicity of the buckled metal oxide substrate, as illustrated in FIG. 2, where the box on the top surface would appear as FIG. 1 upon magnification.

The hole transport layer can be selected from any appropriate material including, but not limited to: 1,1-bis[(di-4-tolylamino)phenyl]cyclohexane (TAPC); N,N′ -diphenyl-N,N′ (2-naphthyl)-(1,1′-phenyl)-4,4′-diamine (NPB); N,N′-diphenyl-N,N′-di(m-tolyl) benzidine (TPD); and poly[(9,9-dioctyl-fluorenyl-2,7-diyl)-alt-co-(9-hexyl-3,6-carbazole)] (PF-9HK). The light emitting layer can be selected from any appropriate material including, but not limited to: tris(2-phenylpyridine) iridium (Ir(ppy)3); poly-[2-methoxy, 5-(2′-ethyl-hexyloxy) phenylene vinylene] (MEH-PPV); tris(8-hydroxy quinoline) aluminum (Alq3); iridium (III) bis[(4,6-di-fluorophenyl)-pyridinate-N,C2′]picolinate (FIrpic); oxadiazole pendant poly(phenylene vinylene); oligo(9,9-di-n-octylfluorene-2,7-vinylene); poly(4-4′-diphenylene diphenylvinylene) (PDPV); poly(9,9-dialkylfluorenes), poly(bisacetylide thiophenes) with BTD or quinoxaline; diphenyloxadiazole pendant polystyrene; 5,6,11,12-tetra-phenylnaphthacene; bis(4′,6′-Difluoro-phenylpyridinato)-4,9-bis-[4-(2,2-diphenyl-vinyl)-phenyl]-naphtho[2,3-c][1,2,5]thiadiazole; 4,4′-bis′2,2′-diphenylvinyl′-1,1′-spirobiphenyl; and fac-tris(2-phenylpyridine) iridium [Ir(ppy)3] doped into a 4,4′-N,N′-dicarbazole-biphenyl.

An additional electron transport layer can be inserted between the electroluminescent layer and the cathode, and can be selected from any appropriate material including, but not limited to: tris [3-(3-pyridyl)-mesityl]borane (3TPYMB); 2,9-Dimethyl-4,7-diphenyl-1,10-phenanthroline (BCP); 4,7-diphenyl-1,10-phenanthroline (BPhen); and tris(8-hydroxy quinoline) aluminum (Alq₃). The top cathode can be transparent or opaque, and can be a metal layer. For example, the cathode can be Aluminum (Al), Silver (Ag), Magnesium Silver (MgAg), Gold (Au), or ITO.

### Methods and Materials

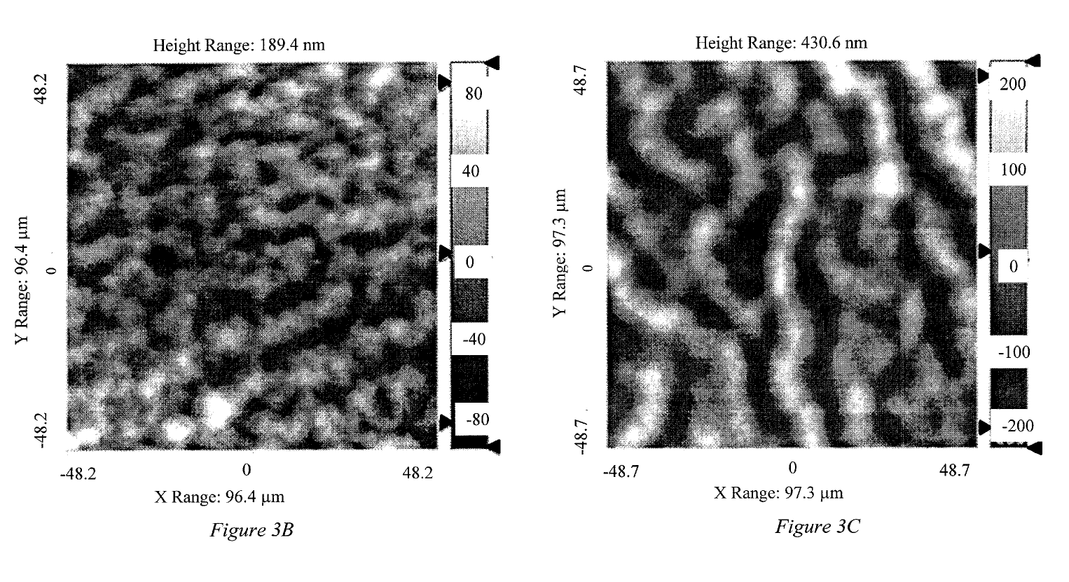

A glass substrate was covered with a polydimethylsiloxane (PDMS) (silicone) layer by spincoating followed by curing at ˜100° C. for 2 hours. The PDMS layer was warmed by the deposited aluminum, and a 15 nm thick aluminum layer was deposited by thermal evaporation. The device was cooled to ambient room temperature (−25° C.) and the aluminum buckled to yield a surface with a fine quasi-periodicity of about 600 nm, as shown in FIG. 3a in an AFM image. The aluminum was oxidized to aluminum oxide upon evaporation on the PDMS, and additional UVO treatment further oxidized the Al layer, which improved the optical transmittance of the aluminum oxide layer. A 70 nm thick ITO anode layer was deposited on the buckled surface, which displayed the gross quasi-periodicity of between 10 and 20 μm that is indicated in the AFM image shown in FIG. 3b. Subsequent deposition of a 50 nm thick NPB layer, a 60 nm thick Alq₃ layer, and a 90 nm thick aluminum layer by thermal evaporation provided a device that displayed a similar quasi-periodicity of between 10 and 20 μm, as indicated in the AFM image shown in FIG. 3c.

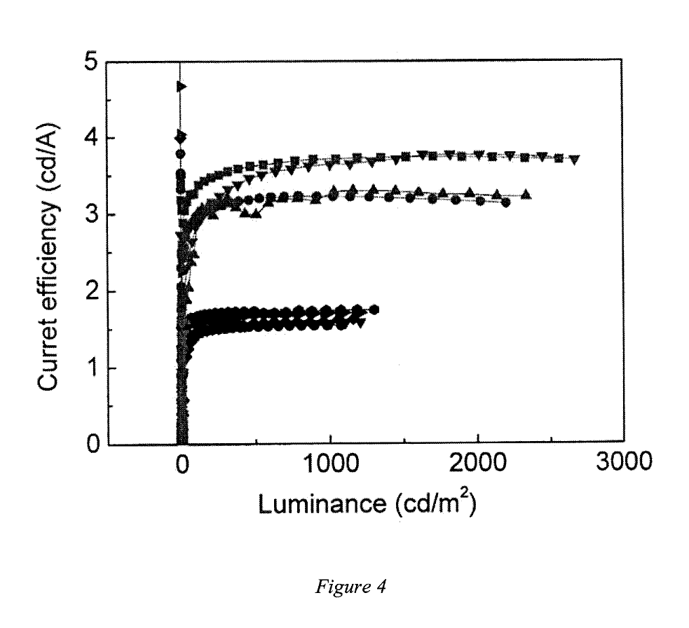

The device was tested for its current efficiency as a function of luminance, as plotted in FIG. 4, for devices where currents versus luminances were measured for four devices with buckling and four devices that do not exhibit buckling. As can be seen in FIG. 4, the average current efficiency without buckling is about 1.7 cd/A and the average efficiency with buckling is about 3.7 cd/A, which is a 120% enhancement due to the quasi-periodic surface extracting the waveguide mode.

All publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

We claim:

1. An organic light emitting diode (OLED) device, comprising a transparent substrate, a transparent elastomeric layer disposed between the transparent substrate and a transparent metal oxide layer that contacts an OLED comprising a transparent anode layer, an electroluminescent layer, and a cathode layer, wherein the OLED has a quasi-periodic buckling, wherein the buckling has a fine buckling and a gross buckling, and wherein the light exiting face of the OLED device is the transparent substrate.

2. The device of claim 1, wherein the fine buckling has a quasi-periodicity of 100 to 700 nm and the gross buckling has a quasi-periodicity of 10 to 20 μm.

3. The device of claim 1, wherein the transparent substrate is glass and the transparent elastomeric layer comprises polydimethylsiloxane (PDMS).

4. The device of claim 1, wherein the transparent anode comprises a conductive metal oxide glass, a transparent metal film of less than 20 nm or a transparent ultrathin metal film of less than 5 nm with a metal grid of spaced apart metal lines with a thickness greater than 20 nm.

5. The device of claim 1, further comprising a hole transport layer.

6. A method of preparing an OLED device, comprising:
providing a transparent substrate;
depositing a transparent elastomeric layer on the transparent substrate;
depositing a metal layer of 20 to 100 nm on the transparent elastomeric layer at an elevated temperature;
reducing the temperature to an ambient temperature, wherein the metal layer buckles to form a buckled metal layer having a fine buckling and a gross buckling;
oxidizing the buckled metal layer, wherein the buckled metal layer transforms into a buckled metal oxide layer;
depositing a transparent anode layer;
depositing an electroluminescent layer; and
depositing a cathode layer, wherein a multilayer OLED is formed wherein the OLED has a quasi-periodic fine buckling and a quasi-periodic gross buckling.

7. The method of claim 6, wherein the substrate comprises a glass or a polymeric material.

8. The method of claim 6, wherein the transparent elastomeric layer is an organic rubber or an inorganic rubber.

9. The method of claim 8, wherein the inorganic rubber comprises polydimethylsiloxane (PDMS).

10. The method of claim 6, wherein the metal layer is aluminum.

11. The method of claim 6, wherein the transparent anode layer is a conductive metal oxide, a transparent metal film of less than 20 nm or a transparent ultrathin metal film of less than 5 nm with an metal grid of spaced apart metal lines with a thickness greater than 20 nm.

12. The method of claim 6, wherein the elevated temperature is at least 30° C. above the ambient temperature.

13. The method of claim 6, further comprising depositing a hole transport layer.
